(19) United States
(12) Patent Application Publication
(10) Pub. No.: US 2019/0195957 A1
(43) Pub. Date: Jun. 27, 2019

(54) SEMICONDUCTOR DEVICE

(71) Applicant: RENESAS ELECTRONICS CORPORATION, Tokyo (JP)

(72) Inventor: Kazuo CHIBA, Tokyo (JP)

(21) Appl. No.: 16/183,391

(22) Filed: Nov. 7, 2018

(30) Foreign Application Priority Data
Dec. 25, 2017 (JP) 2017-247451

(51) Int. Cl. G01R 31/36; H02J 7/00; G06F 7/02; H01M 10/42; H01M 10/48

(52) U.S. Cl. CPC G01R 31/3651; H02J 7/0021; G06F 7/02; G01R 31/3675; H01M 10/486; G01R 31/3662; H01M 10/4285

(57) ABSTRACT

A semiconductor device includes a temperature measurement unit measuring the temperature of a battery cell, a voltage measurement unit measuring the voltage of the battery cell, an electric current measurement unit measuring an electric current supplied from the battery cell, and a control unit. The control unit counts the number of cycles of the charging and discharging of the battery cell, measures the charging rate of the battery cell based on the voltage, measures the internal resistance of the battery cell based on the voltage and the electric current, normalizes the internal resistance based on each of the number of cycles, the temperature, and the charging rate to calculate the shipping internal resistance of the battery cell, and performs, based on the shipping internal resistance, a determination process of whether the battery cell is a non-authenticated product.

### CROSS-REFERENCE TO RELATED APPLICATIONS

The disclosure of Japanese Patent Application No. 2017-247451 filed on Dec. 25, 2017 including the specification, drawings and abstract is incorporated herein by reference in its entirety.

### BACKGROUND

The present invention relates to a semiconductor device.

Rechargeable battery packs are used for various equipment, such as a PC, a DSC, and a DVC. Many non-authenticated battery packs that are less expensive than authenticated battery packs are available. Assembly manufacturers introduce battery authentication technique to detect such the non-authenticated battery packs.

In some non-authenticated battery packs, the substrate of an old authenticated battery pack that has been disposed of is used, or the deteriorated battery cell is replaced with a new battery cell. Such the non-authenticated battery packs pass battery authentication, and thus cannot be effectively detected.

Accordingly, Japanese Unexamined Patent Application Publication No. 2013-132147 (Patent Literature 1) discloses an electric storage device and the like, which can correctly detect non-authenticated battery replacement.

Specifically, the electric storage device has an electric storage unit including at least one electric storage element, a measurement unit measuring the voltage, the electric current, and the temperature of the electric storage element, and a calculation unit calculating the internal resistance of the electric storage element from the voltage, the electric current, and the temperature measured by the measurement unit. And, when detecting the discontinuity of the change with time in the calculated internal resistance, the electric storage device uses a determination unit to determine that the electric storage element has been replaced.

More specifically, the electric storage element, such as a lithium ion secondary battery, has a characteristic in which when the electric storage element is repeatedly used, the internal resistance increases, so that the electric storage device can detect battery replacement from the change in the internal resistance.

### SUMMARY

However, to determine the discontinuity of the change with time in the internal resistance, the electric storage device and the like of Patent Literature 1 disclose only the internal resistance value increase or decrease determination method, which determines whether the change in the measured internal resistance value increases or decreases. On the other hand, the internal resistance value of the authenticated battery pack can be discontinuous due to the deterioration progress when the battery pack is left in no use and the variation in the use environment.

As a result, even the authenticated battery pack can be falsely determined to have been replaced with the non-authenticated battery pack, and on the contrary, even the non-authenticated battery pack can be falsely determined to have been replaced with the authenticated battery pack. Therefore, the electric storage device and the like of Patent Literature 1 cannot correctly detect whether the battery pack is an authenticated product or a non-authenticated product.

Other objects and novel features will be apparent from the description herein and the accompanying drawings.

Semiconductor devices according to a plurality of embodiments are described herein, and the semiconductor device according to one of the embodiments will be described as follows. The semiconductor device includes a temperature measurement unit measuring the temperature of a battery cell, a voltage measurement unit measuring the voltage of the battery cell, an electric current measurement unit measuring an electric current supplied from the battery cell, and a control unit. The control unit counts the number of cycles of the charging and discharging of the battery cell, measures the charging rate of the battery cell based on the voltage measured by the voltage measurement unit, and measures the internal resistance of the battery cell based on the voltage and the electric current measured by the electric current measurement unit. In addition, the control unit normalizes the internal resistance based on each of the number of cycles, the temperature, and the charging rate to calculate the shipping internal resistance of the battery cell, and determines, based on the shipping internal resistance, whether the battery cell is a non-authenticated product.

According to the one embodiment, the non-authenticated battery cell can be detected with high accuracy.

### BRIEF DESCRIPTION OF THE DRAWINGS

FIG. 1 is a circuit diagram illustrating an example of the configuration of a battery pack according to a first embodiment of the present invention;

FIGS. 2A to 2C are graphs illustrating the characteristics of the internal resistance of a battery cell;

FIGS. 3A to 3C are tables illustrating first reference information, second reference information, and third reference information;

FIG. 4 is a chart of assistance in explaining the principle of measuring the internal resistance of the battery cell;

FIG. 5 is a flowchart illustrating an example of the determination process of the battery cell according to the first embodiment of the present invention;

FIG. 6 is a chart illustrating an example of normalized internal resistances according to the first embodiment;

FIG. 7 is a circuit diagram illustrating an example of the configuration of a battery pack according to a second embodiment of the present invention;

FIG. 8 is a circuit diagram illustrating an example of the configuration of a battery pack according to a third embodiment of the present invention;

FIG. 9 is a table illustrating an example of an internal resistance management table; and

FIG. 10 is a flowchart illustrating an example of the determination process of the battery cell according to the third embodiment of the present invention.

### DETAILED DESCRIPTION

Embodiments of the present invention will be described below in detail based on the drawings. Is should be noted that in all the drawings for illustrating the embodiments, the same portions are, as a rule, indicated by similar reference signs, and their repeated description is omitted.

### First Embodiment

<The Configuration of a Battery Pack>

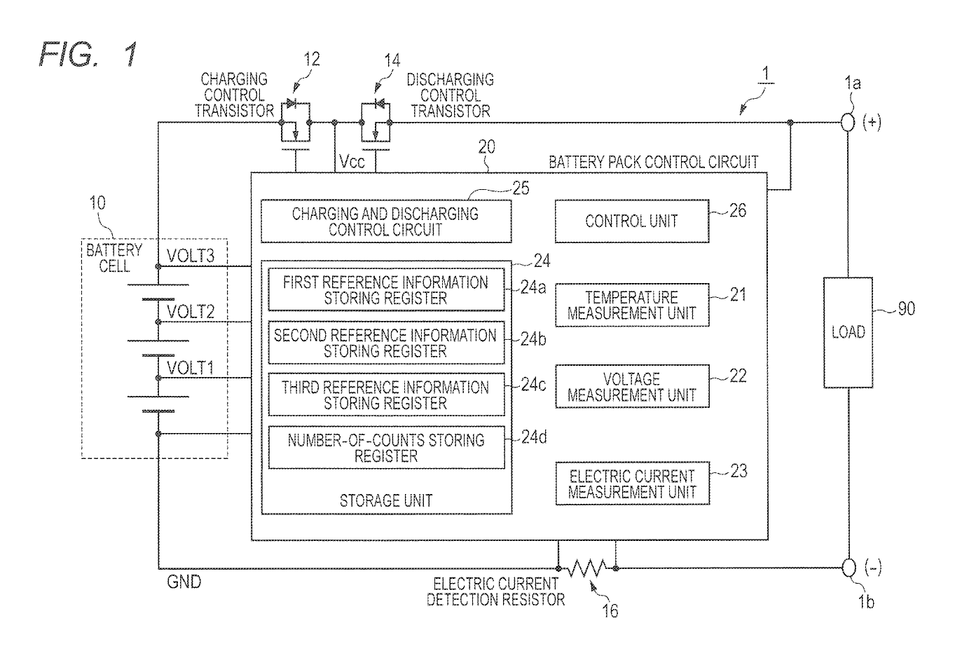

FIG. 1 is a circuit diagram illustrating an example of the configuration of a battery pack according to a first embodiment of the present invention. As illustrated in FIG. 1, a battery pack 1 includes a battery cell 10, a charging control transistor 12, a discharging control transistor 14, an electric current detection resistor 16, and a battery pack control circuit (semiconductor device) 20.

The battery pack 1 is a circuit block coupled to a load 90 through a positive side end 1a and a negative side end 1b and supplying an electric current to the load 90.

The battery cell 10 includes a secondary battery, such as a lithium battery and a lithium ion battery. The battery cell 10 may include a plurality of secondary batteries coupled in series, as illustrated in FIG. 1, or may include a single secondary battery.

The charging control transistor 12 is a circuit element performing electric current control during the charging of the battery cell 10. The charging control transistor 12 includes a field effect transistor, such as a MOSFET (Metal Oxide Semiconductor Field Effect Transistor). As illustrated in FIG. 1, the gate of the charging control transistor 12 is coupled to the battery pack control circuit 20. The charging control transistor 12 performs the electric current control during charging by gate voltage control from the battery pack control circuit 20.

The discharging control transistor 14 is a circuit element performing electric current control during the discharging of the battery cell 10, that is, during the supplying of the electric current to the load 90. The discharging control transistor 14 also includes the field effect transistor. As illustrated in FIG. 1, the gate of the discharging control transistor 14 is also coupled to the battery pack control circuit 20. The discharging control transistor 14 performs the electric current control during discharging by gate voltage control from the battery pack control circuit 20.

The electric current detection resistor 16 is a circuit element detecting the electric current supplied from the battery cell 10. The electric current detection resistor 16 is coupled to the battery pack control circuit 20, and the electric current value is measured by a later-described electric current measurement unit 23 provided in the battery pack control circuit 20.

As illustrated in FIG. 1, the battery pack control circuit 20 includes a temperature measurement unit 21, a voltage measurement unit 22, the electric current measurement unit 23, a storage unit 24, a charging and discharging control circuit 25, and a control unit 26.

The temperature measurement unit 21 is a circuit block measuring the temperature of the battery cell 10. The temperature measurement unit 21 includes a temperature sensor and an A/D converter. The A/D converter converts the temperature measured by the temperature sensor from an analog signal to a digital signal, and feeds the converted digital signal to the control unit 26. The voltage measurement unit 22 is a circuit block measuring the voltage of the battery cell 10. The voltage measurement unit 22 may measure the voltage difference between both ends of the battery cell 10 to measure the voltage of the battery cell 10. Alternatively, the voltage measurement unit 22 may measure the potential difference between both ends of each of the secondary batteries configuring the battery cell 10 to total the potential differences of the respective secondary batteries, thereby calculating the voltage of the battery cell 10. The voltage measurement unit 22 includes a voltage measurement circuit and an A/D converter. The A/D converter converts the voltage measured by the voltage measurement circuit from an analog signal to a digital signal, and feeds the converted digital signal to the control unit 26.

The electric current measurement unit 23 is a circuit block measuring the electric current supplied from the battery cell 10. The electric current measurement unit 23 includes an electric current measurement circuit and an A/D converter. The A/D converter converts the electric current measured by the electric current measurement circuit from an analog signal to a digital signal, and feeds the converted digital signal to the control unit 26.

The storage unit 24 is a circuit block storing various information relating to the battery pack 1. The storage unit 24 includes a non-volatile memory, such as a flash memory and an EEPROM.

As illustrated in FIG. 1, the storage unit 24 includes a first reference information storing register 24a, a second reference information storing register 24b, a third reference information storing register 24c, and a number-of-counts storing register 24d.

The first reference information storing register 24a is a register storing first reference information associating the number of cycles of the charging and discharging of the battery cell 10 with a first normalization coefficient. Here, the first normalization coefficient is a coefficient corresponding to the number of cycles, and is a coefficient used for calculating, from the measurement value of the internal resistance of the battery cell 10, an internal resistance at the time of shipping (a first shipping internal resistance).

The first reference information storing register 24a may store, as the first reference information, a reference table associating the number of cycles with the first normalization coefficient, or may store, as the first reference information, a normalization function f(Cy) deriving the first normalization coefficient in which the number of cycles (Cy) is a variable. It should be noted that the first reference information is written into the first reference information storing register 24a before the shipping of the battery pack 1.

The second reference information storing register 24b is a register storing second reference information associating the temperature of the battery cell 10 with a second normalization coefficient. Here, the second normalization coefficient is a coefficient corresponding to the temperature, and is a coefficient used for calculating, from the measurement value of the internal resistance of the battery cell 10, an internal resistance at the time of shipping (a second shipping internal resistance).

The second reference information storing register 24b may store, as the second reference information, a reference table associating the temperature with the second normalization coefficient, or may store, as the second reference information, a normalization function f(T) deriving the second normalization coefficient in which the temperature (T) is a variable. It should be noted that the second reference information is written into the second reference information storing register 24b before the shipping of the battery pack 1.

The third reference information storing register 24c is a register storing third reference information associating the charging rate of the battery cell 10 with a third normalization coefficient. Here, the third normalization coefficient is a coefficient corresponding to the charging rate, and is a coefficient used for calculating, from the measurement value of the internal resistance of the battery cell 10, an internal resistance at the time of shipping (a third shipping internal resistance).

The third reference information storing register 24c may store, as the third reference information, a reference table associating the charging rate with the third normalization coefficient, or may store, as the third reference information, a normalization function f(SoC) deriving the third normalization coefficient in which the charging rate (SoC: State of Charge) is a variable. It should be noted that the third reference information is written into the third reference information storing register 24c before the shipping of the battery pack 1.

The number-of-counts storing register 24d is a register storing the number of cycles of the charging and discharging of the battery cell 10. Information of the number of cycles stored in the number-of-cycles storing register 24d is supplied from the control unit 26. Alternatively, the number-of-counts storing register 24d may include a counter. In this case, the counter counts, as the number of cycles, the number of times in which the count signal is asserted from the control unit 26.

In addition, the storage unit 24 includes, other than these registers, for example, various registers, such as a register storing the allowable range of the shipping internal resistance of the battery cell 10 allowed as an authenticated product, and a register storing the voltage of the battery cell 10 during full charging.

### Examples of the Characteristics of the Internal Resistance of the Battery Cell and the Normalization Coefficients

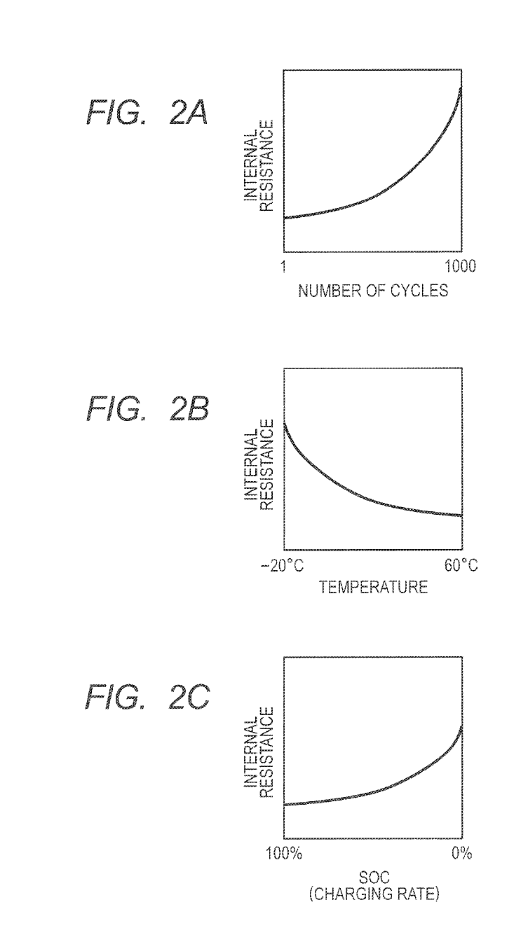

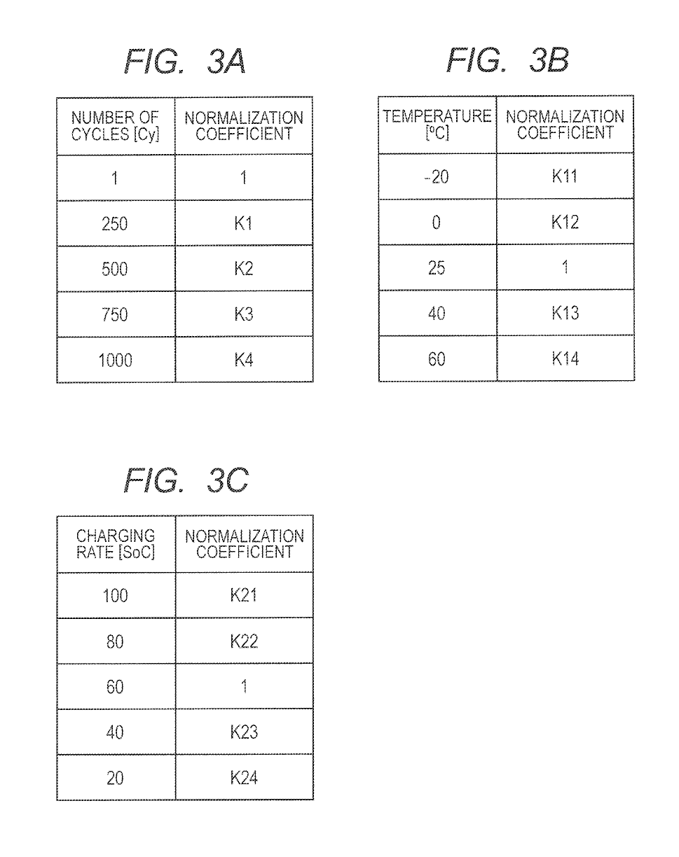

Here, examples of the characteristics of the internal resistance of the battery cell, the first normalization coefficient, the second normalization coefficient, and the third normalization coefficient will be described here with reference to FIGS. 2A to 3C.

FIGS. 2A to 2C are graphs illustrating the characteristics of the internal resistance of the battery cell. FIG. 2A is a graph illustrating the cycle characteristic of the internal resistance. FIG. 2B is a graph illustrating the temperature characteristic of the internal resistance. FIG. 2C is a graph illustrating the charging rate (SoC) characteristic of the internal resistance.

On the other hand, FIGS. 3A to 3C are tables illustrating the first reference information, the second reference information, and the third reference information. FIG. 3A is a table illustrating the reference table associating the number of cycles of the battery cell 10 with the first normalization coefficient. FIG. 3B is a table illustrating the reference table associating the temperature of the battery cell 10 with the second normalization coefficient. FIG. 3C illustrates the reference table associating the charging rate of the battery cell 10 with the third normalization coefficient.

First, the number-of-cycles characteristic of the battery cell 10 will be described. As illustrated in FIG. 2A, as the number of cycles increases, the internal resistance of the battery cell 10 becomes higher. Further, as the number of cycles increases, the increase rate of the internal resistance becomes higher.

On the other hand, the number of cycles is one (Cy=1) at the time of the shipping of the battery pack 1, and as illustrated in FIG. 3A, the first normalization coefficient is set to 1. When the number of cycles is 250, for example, the first normalization coefficient is set to K1 (K1<1). Hereinbelow, as the number of cycles increases, the respective first normalization coefficients are further set to smaller values K2 and K3 (K1>K2>K3). And, when the number of cycles is 1000, for example, the first normalization coefficient is set to K4 (K4<K3).

Next, the temperature characteristic of the battery cell will be described. As illustrated in FIG. 2B, as the temperature increases, the internal resistance of the battery cell 10 becomes lower. Further, as the temperature lowers, the lowering rate of the internal resistance becomes higher.

On the other hand, when the temperature of the battery cell 10 is 25° C. (T=25) at the time of the shipping of the battery pack 1, the second normalization coefficient at this temperature is set to 1, as illustrated in FIG. 3B. When the temperature is 0° C., for example, the second normalization coefficient is set to K12 (K12<1). Further, when the temperature is −20° C., for example, the second normalization coefficient is set to K11 (K11<K12). Furthermore, when the temperatures are 40° C. and 60° C., for example, the respective second normalization coefficients are set to K13 and K14 (1<K13<K14).

Next, the charging rate characteristic of the battery cell 10 will be described. As illustrated in FIG. 2C, as the charging rate lowers, the internal resistance of the battery cell 10 becomes higher. In addition, as the charging rate lowers, the increase rate of the internal resistance becomes higher.

On the other hand, when the charging rate of the battery cell 10 is 60% (SoC=60) at the time of the shipping of the battery pack 1, the third normalization coefficient at this charging rate is set to 1, as illustrated in FIG. 3C. When the charging rates are 40% and 20%, for example, the respective third normalization coefficients are set to K23 and K24 (K24<K23<1). On the other hand, when the charging rates are 80% and 100%, the respective third normalization coefficients are set to K22 and K21 (1<K22<K21).

It should be noted that the characteristics of the battery cell 10 are not limited to such the examples. For example, contrary to the examples in FIGS. 2A and 3A, as the number of cycles increases, the internal resistance of the battery cell 10 can be lower. In addition, contrary to the examples in FIGS. 2B and 3B, as the temperature increases, the internal resistance of the battery cell 10 can be higher. Further, contrary to the examples in FIGS. 2C and 3C, as the charging rate lowers, the internal resistance of the battery cell 10 can be higher.

Here, the description of the battery pack control circuit 20 will be returned. The charging and discharging control circuit 25 is a circuit block controlling the electric current during the charging and discharging of the battery cell 10. Specifically, the charging and discharging control circuit 25 controls the gate voltages of the charging control transistor 12 and the discharging control transistor 14 to control the electric current during charging and discharging.

The control unit 26 is a circuit controlling each operation of the battery pack control circuit 20. For example, the control unit 26 feeds the electric current control signal to the charging and discharging control circuit 25 to control the electric current during the charging and discharging of the battery cell 10. In addition, the control unit 26 counts the number of cycles of the charging and discharging of the battery cell 10 to store the counted number of cycles in the number-of-counts storing register 24d. Alternatively, when the charging rate of the battery cell 10 is reached, the control unit 26 may assert the count signal.

In addition, the control unit 26 measures the charging rate of the battery cell 10. Specifically, the control unit 26 calculates the charging rate of the battery cell 10 based on the voltage of the battery cell 10 measured by the voltage measurement unit 22 and the voltage of the battery cell 10 during full charging. In addition, the control unit 26 measures the internal resistance of the battery cell 10. Specifically, the control unit 26 measures the internal resistance of the battery cell 10 based on the measured voltage of the battery cell 10 and the electric current of the battery cell 10 measured by the electric current measurement unit 23.

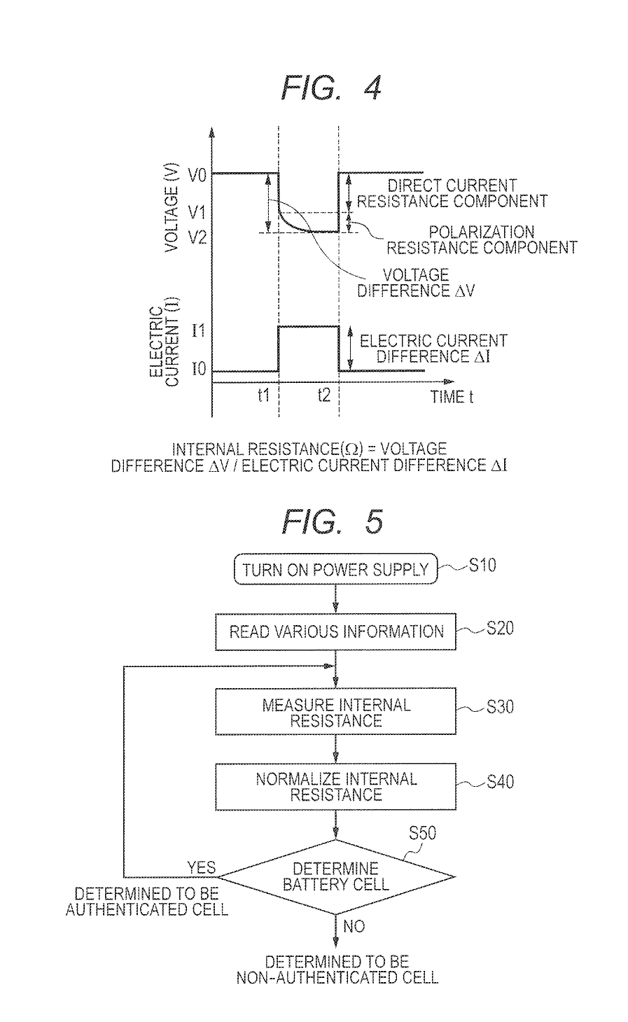

FIG. 4 is a chart of assistance in explaining the principle of measuring the internal resistance of the battery cell. The upper stage of FIG. 4 is a timing chart illustrating the variation in the voltage of the battery cell 10. The lower stage of FIG. 4 is a timing chart illustrating the variation in the electric current of the battery cell 10.

When discharging is started at time t1, the voltage of the battery cell 10 suddenly lowers from V0 to V1, as illustrated in FIG. 4. On the other hand, the electric current supplied from the battery cell 10 suddenly increases from I0 to I1. At this time, the voltage of the battery cell 10 is influenced mainly by the direct current resistance component of the internal resistance.

Thereafter, during the period until time t2, the voltage of the battery cell 10 gently lowers from V1 to V2. On the other hand, the electric current remains at I1, and hardly varies. During this period, the voltage of the battery cell 10 is influenced mainly by the polarization resistance component of the internal resistance. After the voltage is influenced by the polarization resistance component and is settled, the control unit 26 measures the internal resistance of the battery cell 10. Therefore, the control unit 26 measures the internal resistance of the battery cell 10 from the voltage difference ΔV (=V0−V2) between the time t1 and the time t2 and the electric current difference ΔI (=I1−I0) during this period.

In addition, the control unit 26 normalizes the internal resistance based on each of the number of cycles, the temperature, and the charging rate of the battery cell 10, and calculates the internal resistance at the time of the shipping of the battery cell 10 (hereinafter, also called a shipping internal resistance).

In addition, the control unit 26 determines, based on the calculated shipping internal resistance, whether the battery cell 10 is a non-authenticated product. These processes will be described later.

<The Determination Process of the Battery Cell>

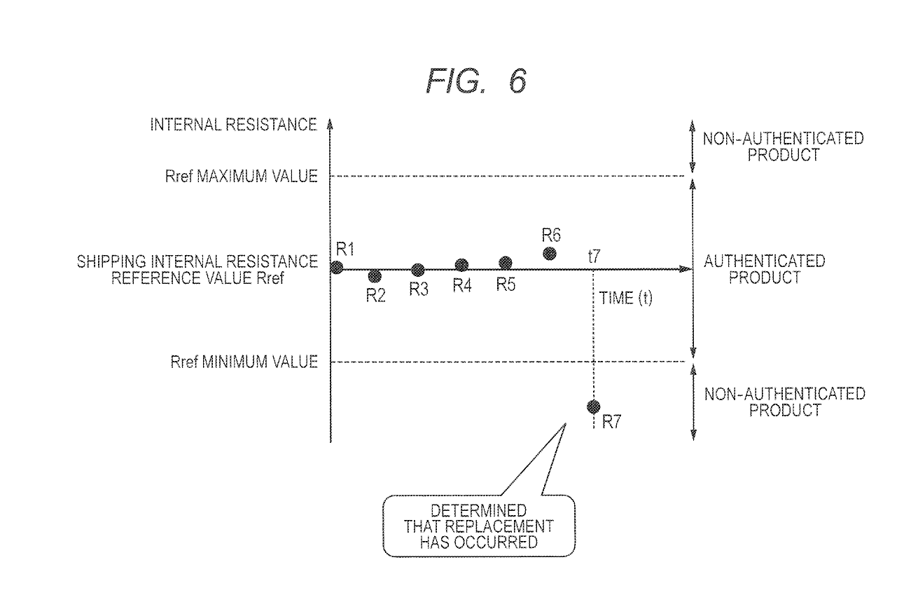

Next, the determination process of the battery cell 10 will be described. FIG. 5 is a flowchart illustrating an example of the determination process of the battery cell according to the first embodiment of the present invention. The determination process of the battery cell 10 is performed in steps S10 to S50 illustrated in FIG. 5.

Step S10

Step S10 is a step of starting the supplying of the electric current to the load 90. When the power supply of the load 90 is turned on, the battery pack 1 supplies the electric current to the load 90. Specifically, the charging and discharging control circuit 25 controls the gate voltages of the charging control transistor 12 and the discharging control transistor 14 based on the electric current control signal fed from the control unit 26, thereby supplying the electric current to the load 90.

Step S20

Step S20 is a step of reading various information used for the determination process of the battery cell 10. Specifically, the control unit 26 reads the first reference information, the second reference information, and the third reference information from the first reference information storing register 24a, the second reference information storing register 24b, and the third reference information storing register 24c, respectively. In addition, the control unit 26 reads the number of cycles of the charging and discharging from the number-of-counts storing register 24d.

In addition, the control unit 26 reads, from the storage unit 24, the allowable range of the shipping internal resistance of the battery cell 10, the voltage of the battery cell 10 during full charging, and the like. The control unit 26 buffers, in its interior, these various information read from the storage unit 24.

Step S30

Step S30 is a step of measuring the internal resistance and the like of the battery cell 10. When the control unit 26 asserts the voltage measurement signal, the voltage measurement unit 22 measures the voltage of the battery cell 10, thereby supplying the measured voltage to the control unit 26. In addition, when the control unit 26 asserts the electric current measurement signal, the electric current measurement unit 23 measures the electric current supplied from the battery cell 10, thereby supplying the measured electric current to the control unit 26.

In addition, when the control unit 26 asserts the temperature measurement signal, the temperature measurement unit 21 measures the temperature of the battery cell 10, thereby supplying the measured temperature to the control unit 26.

And, the control unit 26 calculates the internal resistance of the battery cell 10 based on the measured voltage and electric current. In addition, the control unit 26 calculates the charging rate of the battery cell 10 based on the measured voltage and the voltage of the battery cell 10 during full charging.

It should be noted that the timing at which the voltage is measured and the timing at which the electric current is measured are desirably substantially the same. With this, the more correct internal resistance can be measured. In addition, the timing at which the temperature is measured is preferably substantially the same as the timing at which the voltage is measured and the timing at which the electric current is measured. With this, the more appropriate normalization coefficient is selected, so that the more correct shipping internal resistance can be calculated.

Step S40

Step S40 is a step of calculating the shipping internal resistance. The control unit 26 derives, from the first reference information, the first normalization coefficient corresponding to the read number of cycles of the battery cell 10. And, the control unit 26 multiplies the internal resistance of the battery cell 10 measured in step S30 by the derived first normalization coefficient to calculate the first shipping internal resistance.

In addition, the control unit 26 derives, from the second reference information, the second normalization coefficient corresponding to the temperature measured in step S30. And, the control unit 26 multiplies the internal resistance of the battery cell 10 measured in step S30 by the derived second normalization coefficient to calculate the second shipping internal resistance.

In addition, the control unit 26 derives, from the third reference information, the third normalization coefficient corresponding to the charging rate measured in step S30. And, the control unit 26 multiplies the internal resistance of the battery cell 10 measured in step S30 by the derived third normalization coefficient to calculate the third shipping internal resistance.

Step S50

Step S50 is a step of determining whether the battery cell 10 is a non-authenticated product. The control unit 26 compares each of the first shipping internal resistance, the second shipping internal resistance, and the third shipping internal resistance with the allowable range of the shipping internal resistance read in step S20. And, when any one of the first shipping internal resistance, the second shipping internal resistance, and the third shipping internal resistance is outside the allowable range (No), the control unit 26 determines that the battery cell 10 to be determined is a non-authenticated product.

On the other hand, when all of the first shipping internal resistance, the second shipping internal resistance, and the third shipping internal resistance are within the allowable range (Yes), the control unit 26 determines that the battery cell 10 to be determined is an authenticated product. In this case, as illustrated in FIG. 5, the control unit 26 repeatedly executes steps S30 to S50, and successively performs the determination process of whether the battery cell 10 is a non-authenticated product.

It should be noted that the determination process of the battery cell 10 is not limited to such the case. For example, the control unit 26 may directly read the first normalization coefficient corresponding to the number of cycles from the first reference information storing register 24a, may directly read the second normalization coefficient corresponding to the temperature from the second reference information storing register 24b, and may directly read the third normalization coefficient corresponding to the charging rate from the third reference information storing register 24c.

### An Example of the Determination Process of the Battery Cell

FIG. 6 is a chart illustrating an example of the normalized internal resistances according to the first embodiment. The abscissa axis in FIG. 6 represents the time, and the ordinate axis in FIG. 6 represents the internal resistance (the calculated shipping internal resistance). FIG. 6 illustrates the minimum value (Rref minimum value) and the maximum value (Rref maximum value) of a shipping internal resistance Rref. And, the allowable range of the shipping internal resistance is defined from the minimum value to the maximum value of the shipping internal resistance.

Respective resistance values R1 to R7 illustrated in FIG. 6 are the shipping internal resistances calculated at the respective different times. As illustrated in FIG. 6, the resistance values R1 to R6 are within the allowable range, and in this case, the control unit 26 determines that the battery cell 10 to be determined is an authenticated product. On the other hand, the resistance value R7 calculated at time t7 is below the minimum value of the allowable range, and thus, the control unit 26 determines that the battery cell 10 to be determined is a non-authenticated product. That is, the control unit 26 determines that the replacement of the battery cell has occurred during this period.

### Effects According to this Embodiment

Here, main effects according to this embodiment will be described. According to this embodiment, the control unit 26 calculates the first shipping internal resistance of the battery cell 10 based on the number of cycles of the battery cell 10, the control unit 26 calculates the second shipping internal resistance of the battery cell 10 based on the temperature of the battery cell 10, and the control unit 26 calculates the third shipping internal resistance of the battery cell 10 based on the charging rate of the battery cell 10. And, the control unit 26 compares each of the first shipping internal resistance, the second shipping internal resistance, and the third shipping internal resistance with the allowable range of the shipping internal resistance, and when any one of the shipping internal resistances is outside the allowable range, the control unit 26 determines that the battery cell 10 is a non-authenticated product.

According to this configuration, the internal resistance at the time of the shipping of the battery cell 10 can be estimated from the measurement value of each of the number of cycles, the temperature, the charging rate, and the internal resistance, so that the non-authenticated battery cell can be detected with high accuracy. Also, it is possible to detect the non-authenticated battery cell without continuously performing the calculation and comparison of the shipping internal resistance of the battery cell. Also, the replacement of the authenticated battery cell with the non-authenticated battery cell can be detected with high accuracy. Also, since the discontinuity of the internal resistance is not required to be considered, the determination process can be easily executed.

Also, according to this embodiment, the control unit 26 multiplies the first normalization coefficient by the measured internal resistance to calculate the first shipping internal resistance of the battery cell 10, multiplies the second normalization coefficient by the measured internal resistance to calculate the second shipping internal resistance of the battery cell 10, and multiplies the third normalization coefficient corresponding to the charging rate by the measured internal resistance to calculate the third shipping internal resistance of the battery cell 10.

According to this configuration, the process for calculating the first shipping internal resistance, the second shipping internal resistance, and the third shipping internal resistance can be simplified, so that the load of the control unit 26 is reduced and the determination process is faster.

Also, according to this embodiment, the control unit 26 derives the first normalization coefficient corresponding to the number of cycles from the first reference information, derives the second normalization coefficient corresponding to the measured temperature from the second reference information, and derives the third normalization coefficient corresponding to the measured charging rate from the third reference information. Also in this configuration, the process for deriving the first normalization coefficient, the second normalization coefficient, and the third normalization coefficient can be simplified, so that the load of the control unit 26 is reduced and the determination process is faster.

Also, according to this embodiment, the first reference information, the second reference information, the third reference information include the tables. According to this embodiment, also in this configuration, the process for deriving the first normalization coefficient, the second normalization coefficient, and the third normalization coefficient can be simplified, so that the load of the control unit 26 is reduced and the determination process is faster.

Also, according to this embodiment, the first reference information, the second reference information, the third reference information include the normalization coefficients. Also in this configuration, the capacity of the first reference information storing register 24a, the second reference information storing register 24b, and the third reference information storing register 24c can be reduced.

Also, according to this embodiment, the first reference information, the second reference information, and the third reference information are written into the first reference information storing register 24a, the second reference information storing register 24b, and the third reference information storing register 24c, respectively, before the shipping of the battery cell 10. According to this configuration, the first reference information, the second reference information, the third reference information are not required to be obtained in each determination process, so that the determination process is faster.

Also, according to this embodiment, even when determining that the battery cell 10 is an authenticated product, the control unit 26 calculates the first shipping internal resistance, the second shipping internal resistance, and the third shipping internal resistance again, and performs the determination process of the battery cell 10. According to this configuration, even if the battery cell 10 is falsely determined to be an authenticated product in the previous determination process, the determination process is performed with respect to the same battery cell 10 again, so that the accuracy of the determination process can be further improved.

### Second Embodiment

Next, a second embodiment of the present invention will be described. In the first embodiment, the shipping internal resistance corresponding to each of the number of cycles, the temperature, and the charging rate and the allowable range of the shipping internal resistance are compared individually. In this case, the measured internal resistance depends on each of the number of cycles, the temperature, and the charging rate, but the first normalization coefficient, the second normalization coefficient, and the third normalization coefficient are mutually independent between the number of cycles, the temperature, and the charging rate. Consequently, the case where the accuracy of the calculated first shipping internal resistance, the calculated second shipping internal resistance, and the calculated third shipping internal resistance is not sufficiently secured can occur.

Accordingly, in this embodiment, the case where the normalization coefficient in consideration of a combination of the number of cycles, the temperature, and the charging rate is derived to perform the determination process of the battery cell 10 will be described. Hereinbelow, it should be noted that the description of the portions overlapped with the above embodiment is omitted as a rule.

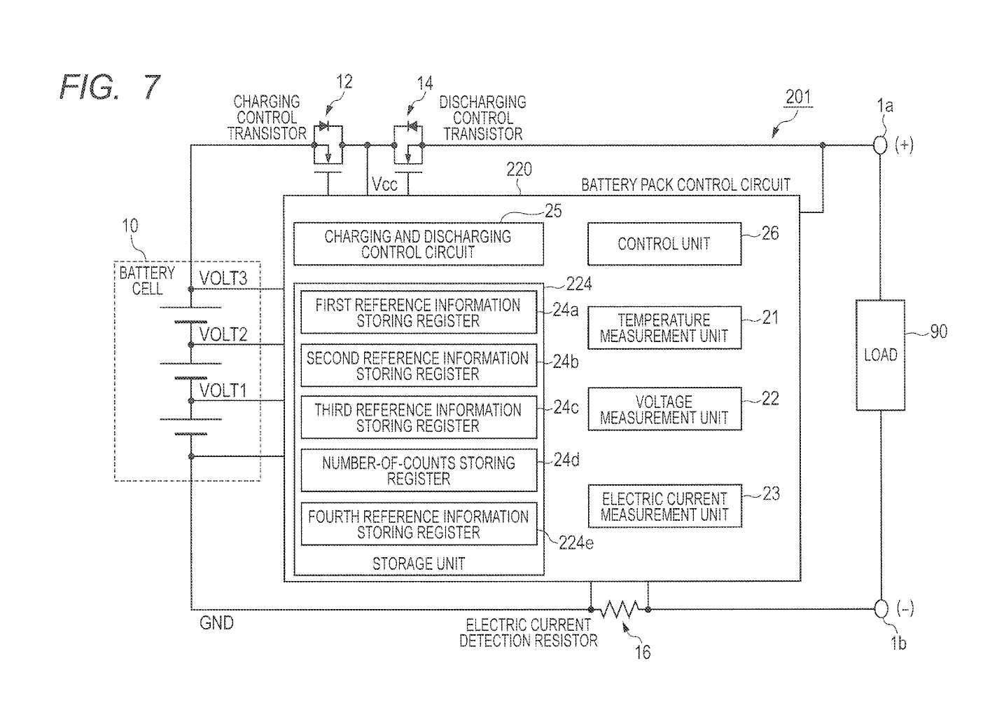

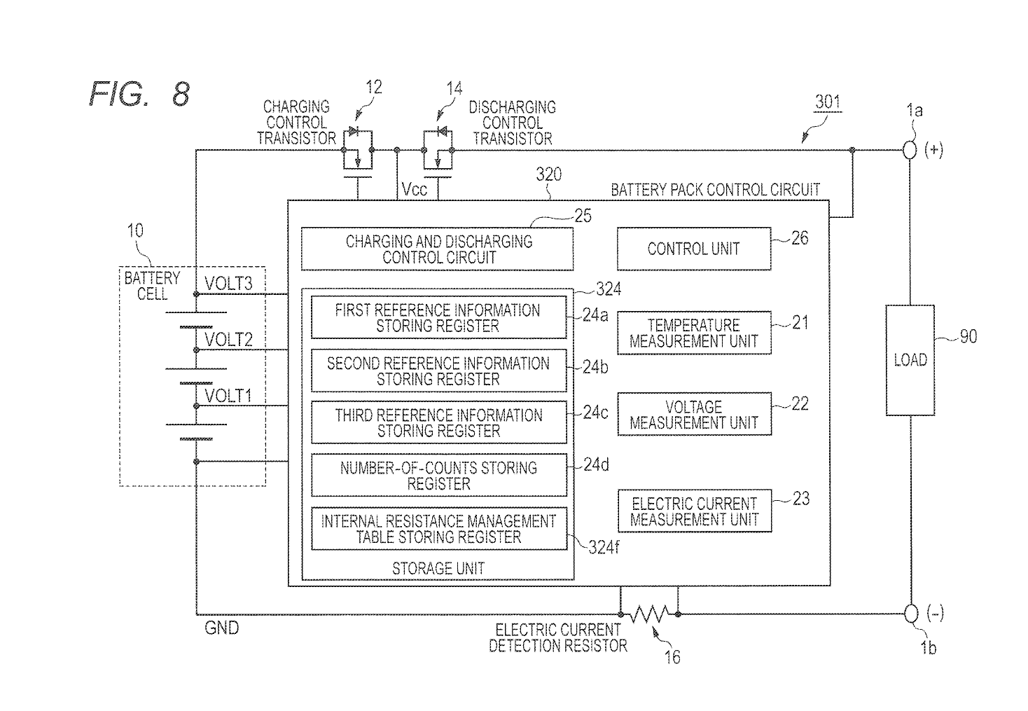

FIG. 7 is a circuit diagram illustrating an example of the configuration of a battery pack according to the second embodiment of the present invention. In a battery pack 201 illustrated in FIG. 7, the battery pack control circuit 20 illustrated in FIG. 1 is replaced with a battery pack control circuit 220. And, in the battery pack control circuit 220, the storage unit 24 illustrated in FIG. 1 is replaced with a storage unit 224. Specifically, in the storage unit 224, a fourth reference information storing register 224e is added to the storage unit 24 illustrated in FIG. 1.

The fourth reference information storing register 224e is a register storing fourth reference information associating a combination of the number of cycles, the temperature, and the charging rate of the battery cell 10 with a fourth normalization coefficient. Here, the fourth normalization coefficient is a coefficient corresponding to a combination of the number of cycles, the temperature, and the charging rate, and is a coefficient used for calculating, from the measurement value of the internal resistance of the battery cell 10, an internal resistance at the time of shipping (a fourth shipping internal resistance).

The fourth reference information storing register 224e may store, as the fourth reference information, a reference table associating a combination of the number of cycles, the temperature, and the charging rate with the fourth normalization coefficient, or may store, as the fourth reference information, a normalization function f(Cy, T, SoC) deriving the fourth normalization coefficient in which the number of cycles (Cy), the temperature (T), and the charging rate (SoC) are as variables. It should be noted that the fourth reference information is written into the fourth reference information storing register 224e before the shipping of the battery pack 1.

<The Determination Process of the Battery Cell>

Next, the determination process of the battery cell 10 according to this embodiment will be described along FIG. 5. It should be noted that steps S10 and S30 are the same as the first embodiment, and their description is omitted.

In step S20, the control unit 26 reads the already described fourth reference information from the fourth reference information storing register 224e. In addition, the processes other than this are the same as the first embodiment.

In step S40, the control unit 26 derives, from the fourth reference information, the fourth normalization coefficient corresponding to a combination of the read number of cycles of the battery cell 10, the measured internal resistance of the battery cell 10, and the measured charging rate of the battery cell 10. And, the control unit 26 multiplies the internal resistance of the battery cell 10 measured in step S30 by the derived fourth normalization coefficient to calculate the fourth shipping internal resistance.

In addition, other than the method described here, the control unit 26 may multiply the first normalization coefficient, the second normalization coefficient, and the third normalization coefficient derived in step S40 in the first embodiment to derive the fourth normalization coefficient. For example, when the fourth reference information includes the normalization coefficient f(Cy, T, SoC), the fourth normalization coefficient is f(Cy, T, SoC)=f(Cy)×f(T)×f(SoC).

In step S50, the control unit 26 compares the fourth shipping internal resistance with the allowable range of the shipping internal resistance read in step S20. And, when the fourth shipping internal resistance is outside the allowable range, the control unit 26 determines that the battery cell 10 is a non-authenticated product.

On the other hand, when determining that the battery cell 10 is an authenticated product, the control unit 26 repeatedly executes steps S30 to S50, as illustrated in FIG. 5, and successively performs the determination process of whether the battery cell 10 is a non-authenticated product.

### Main Effects According to this Embodiment

According to this embodiment, in addition to the already described effects, the following effects can be obtained. According to this embodiment, the shipping internal resistance based on a combination of the number of cycles, the temperature, and the charging rate can be calculated, so that the determination process of the battery cell 10 can be executed with higher accuracy.

### Third Embodiment

Next, a third embodiment of the present invention will be described. In the above embodiments, the measured internal resistance is normalized to calculate the shipping internal resistance, and the determination process of the battery cell 10 of whether the shipping internal resistance is within the allowable range is performed. On the contrary, in this embodiment, the measured internal resistance is recorded into a predetermined management table to compare the measured internal resistance with the internal resistance recorded into the table, thereby performing the determination process of the battery cell 10. That is, in this embodiment, the determination process of the battery cell 10 is performed without normalizing the measured internal resistance.

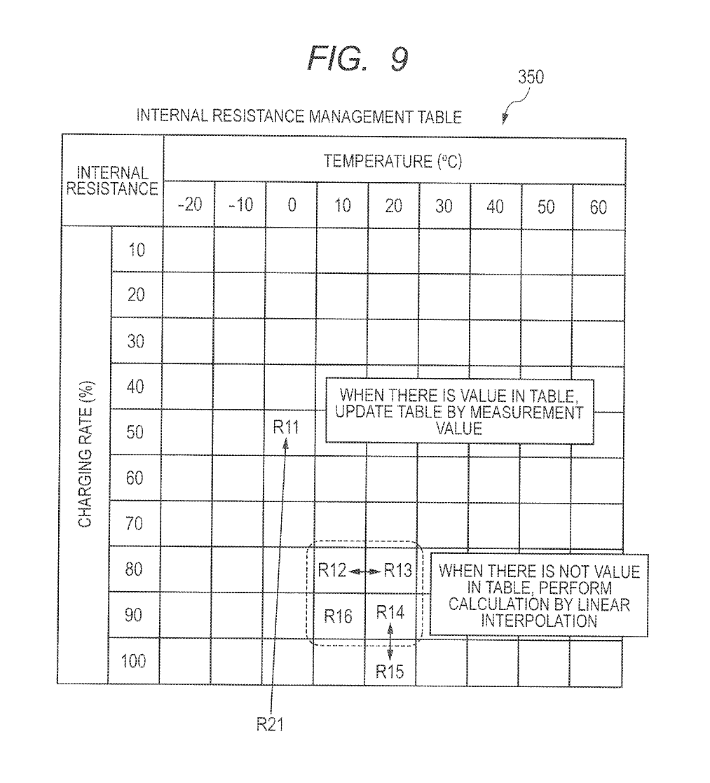

FIG. 8 is a circuit diagram illustrating an example of the configuration of a battery pack according to the third embodiment of the present invention. In addition, FIG. 9 is a table illustrating an example of an internal resistance management table. In a battery pack 301 illustrated in FIG. 8, the battery pack control circuit 20 illustrated in FIG. 1 is replaced with a battery pack control circuit 320. And, in the battery pack control circuit 320, the storage unit 24 illustrated in FIG. 1 is replaced with a storage unit 324. Specifically, in the storage unit 324, an internal resistance management table storing register 324f is added to the storage unit 24 illustrated in FIG. 1.

The internal resistance management table storing register 324f is a register storing an internal resistance management table 350 illustrated in FIG. 9. As illustrated in FIG. 9, the internal resistance management table 350 includes a temperature recording axis (abscissa axis) and a charging rate recording axis (ordinate axis). The internal resistance management table 350 records the measured internal resistance so as to associate the measured internal resistance with the temperature and the charging rate during measurement. The internal resistance management table 350 records the measured internal resistance only when the battery cell to be determined is determined to be an authenticated product. The internal resistance management table 350 may be stored in the internal resistance management table storing register 324f before the shipping of the battery cell 10.

Specifically, another authenticated battery cell before shipping is used to measure the internal resistance in a state where the conditions of the temperature and the charging rate are made different. It should be noted that the number of cycles at this time is “1”. And, the internal resistance management table is created based on the internal resistance measured under the respective conditions, and the created internal resistance management table is then stored in the internal resistance management table storing register 324f of the battery pack shipped. It should be noted that during the creation of the internal resistance management table, the internal resistances of a plurality of authenticated battery cells may be measured to create the internal resistance management table based on the value obtained by calculating the average of these.

In addition, other than these registers, for example, the storage unit 324 includes various registers, such as a register storing a difference allowable range allowed as an authenticated product.

Here, the difference allowable range will be described. The difference allowable range is information used for determining whether the battery cell 10 to be determined is a non-authenticated product. When the internal resistance at the same temperature and at the same charging rate is measured again, the control unit 26 compares the measured internal resistance with the corresponding internal resistance recorded into the internal resistance management table 350, and performs the determination process of whether the battery cell 10 is a non-authenticated product.

Specifically, the control unit 26 calculates the difference between the measured internal resistance and the internal resistance recorded into the internal resistance management table 350, and compares the difference with the difference allowable range. And, when the calculated difference is within the difference allowable range, the control unit 26 determines that the battery cell 10 to be determined is an authenticated product, and when the calculated difference is outside the difference allowable range, the control unit 26 determines that the battery cell 10 to be determined is a non-authenticated product. In this way, the difference allowable range is used for the determination process of the battery cell 10.

It should be noted that as already described in connection with FIG. 2A, as the number of cycles increases, the increase rate of the internal resistance becomes higher. Thus, as the number of cycles increases, the difference is considered to become larger, so that when the number of cycles reaches a predetermined number of times, the difference allowable range may be switched to the larger difference allowable range to execute the determination process.

### Attitude to this Embodiment

The allowable range used in the above embodiments is defined in the section from the minimum value (Rref minimum) to the maximum value (Rref maximum) of the shipping internal resistance Rref. In addition, as already described, from the measured internal resistance Rcel of the battery cell 10 and the normalization coefficient f (Cy, T, SoC), the shipping internal resistance Rref is Rref=Rcel×f (Cy, T, SoC).

When this equation is applied to the conditions of the allowable range of the shipping internal resistance Rref, Rcel×f (Cy, T, SoC) is “Rref minimum<Rcel×f (Cy, T, SoC)<Rref maximum”. When this equation is further rearranged, the Rcel is “Rref minimum/f (Cy, T, SoC)<Rcel<Rref maximum/f (Cy, T, SoC)”.

Rref/f (Cy, T, SoC) represented here is obtained by non-normalizing the original internal resistance of the battery cell 10, that is, the internal resistance measurement value of the battery cell 10 depending on the respective conditions of the number of cycles, the temperature, and the charging rate. In the attitude to this embodiment, when the measured internal resistance is within the range from Rref minimum/f(Cy, T, SoC) to Rref maximum/f(Cy, T, SoC), the battery cell 10 is an authenticated product.

However, in one cycle or several cycles, the internal resistance measurement value does not greatly increase, and the number of cycles does not decrease, so that the internal resistance management table records the measured internal resistance by using the temperature and the charging rate as the recording axes. Thus, when chronologically observed, the internal resistance measured under the same conditions can be considered to be the function in which the number of cycles is a variable.

<The Determination Process of the Battery Cell>

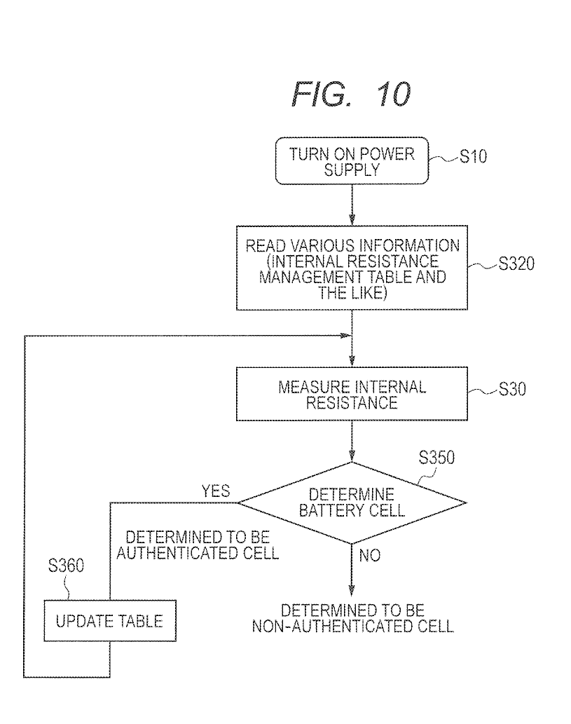

Next, the determination process of the battery cell 10 according to this embodiment will be described. FIG. 10 is a flowchart illustrating an example of the determination process of the battery cell according to the third embodiment of the present invention. As illustrated in FIG. 10, the determination process of the battery cell 10 according to this embodiment is performed in steps S10 to S360. It should be noted that steps S10 and S30 are the same as the first and second embodiments, and their description is omitted.

Step S320

Step S320 is similar to step S20 in FIG. 5, and is a step of reading various information used for the determination process of the battery cell 10. Specifically, the control unit 26 reads the internal resistance management table 350 from the internal resistance management table storing register 324f. In addition, the control unit 26 reads the difference allowable range, the voltage of the battery cell 10 during full charging, and the like, from the storage unit 24. The control unit 26 buffers, in its interior, these various information read from the storage unit 24.

Steps S350 and S360

Step S350 is a step of determining whether the battery cell 10 is a non-authenticated product.

When measuring the internal resistance of the battery cell 10 and the conditions during measurement (the temperature and the charging rate) in step S30, the control unit 26 compares the measured internal resistance with the corresponding internal resistance recorded into the internal resistance management table 350, and performs the determination process of whether the battery cell 10 to be determined is a non-authenticated product. Specifically, the difference between the measured internal resistance and the corresponding internal resistance recorded into the internal resistance management table 350 is calculated to compare the difference with the difference allowable range. When the difference is outside the difference allowable range (No), the control unit 26 determines that the battery cell 10 to be determined is a non-authenticated product.

On the other hand, when the difference is within the difference allowable range (Yes), the control unit 26 determines that the battery cell 10 to be determined is an authenticated product. In this case, the control unit 26 executes the process in step S360. Step S360 is a step of recording the measured internal resistance into the internal resistance management table 350. The control unit 26 records the measured internal resistance into the corresponding portion of the internal resistance management table 350.

For example, as illustrated in FIG. 9, an internal resistance R11 corresponding to the temperature=0° C. and the charging rate=50% is recorded into the internal resistance management table 350. Assume that the control unit 26 measures a new internal resistance R21 under the same conditions. At this time, when the battery cell 10 is determined to be an authenticated product, the control 26 updates the original internal resistance R11 recorded into the internal resistance management table 350 to the new internal resistance R21.

When step S360 is completed, the control unit 26 repeatedly executes steps S30 to S350, as illustrated in FIG. 10, and successively performs the determination process of whether the battery cell 10 is a non-authenticated product.

It should be noted that also in this embodiment, the determination process of the battery cell 10 is not limited to such the case. For example, the control unit 26 may directly read the internal resistance management table 350 from the internal resistance management table storing register 324f, or may directly update the internal resistance management table stored in the internal resistance management table storing register 324f.

The case where the temperature recording axis corresponding to the temperature during measurement is not provided

The process in the case where the temperature recording axis corresponding to the temperature during measurement is not provided will be described with reference to FIG. 9.

When the temperature recording axis corresponding to the temperature during measurement is not provided, the control unit 26 calculates a temperature interpolation internal resistance based on the internal resistance corresponding to the temperature during measurement on each of the temperature recording axes corresponding to a plurality of temperatures near the temperature during measurement.

For example, assume that the internal resistance is measured under the temperature=15° C. and the charging rate=80%. However, the temperature recording axis corresponding to 15° C. is not provided in the internal resistance management table 350, so that here, liner interpolation is performed based on an internal resistance R12 corresponding to the temperature=10° C. and the charging rate=80% and an internal resistance R13 corresponding to the temperature=20° C. and the charging rate=80%, and an internal resistance corresponding to the temperature=15° C. and the charging rate=80% (temperature interpolation internal resistance) is then calculated.

And, the control unit 26 calculates the difference between the measured internal resistance and the temperature interpolation internal resistance, and compares the difference with the difference allowable range, thereby performing the determination process of the battery cell 10.

The case where the charging rate recording axis corresponding to the charging rate during measurement is not provided

The same process as the process with respect to the temperature is performed with respect to the charging rate.

When the charging rate recording axis corresponding to the charging rate during measurement is not provided, the control unit 26 calculates a charging rate interpolation internal resistance based on the internal resistance corresponding to the charging rate during measurement on each of the charging rate recording axes corresponding to a plurality of charging rates near the charging rate during measurement.

For example, assume that the internal resistance is measured under the conditions of the temperature=20° C. and the charging rate=95%. However, the charging rate recording axis corresponding to 95% is not provided in the internal resistance management table 350, so that here, liner interpolation is performed based on an internal resistance R14 corresponding to the temperature=20° C. and the charging rate=90% and an internal resistance R15 corresponding to the temperature=20° C. and the charging rate=100%, and an internal resistance corresponding to the temperature=20° C. and the charging rate=95% (charging rate interpolation internal resistance) is then calculated.

And, the control unit 26 calculates the difference between the measured internal resistance and the charging rate interpolation internal resistance, and compares the difference with the difference allowable range, thereby performing the determination process of the battery cell 10.

[The Case where the Recording Axes Corresponding to the Temperature and the Charging Rate During Measurement are not Provided]

Of course, there can also be the case where the recording axes corresponding to both of the temperature and the charging rate during measurement are not provided. In this case, an internal resistance (temperature and charging rate interpolation internal resistance) is calculated based on the internal resistance corresponding to the temperature and the charging rate during measurement on each of the temperature recording axes and each of the charging rate recording axes corresponding to a plurality of temperatures and a plurality of charging rates near the conditions during measurement.

For example, when the internal resistance is measured under the conditions of the temperature=15° C. and the charging rate=85%, liner interpolation is performed based on the internal resistance R12 corresponding to the temperature=10° C. and the charging rate=80% and the internal resistance R14 corresponding to the temperature=20° C. and the charging rate=90%, and a corresponding internal resistance (temperature and charging rate interpolation internal resistance) is then calculated. Alternatively, liner interpolation may be performed based on an internal resistance R16 corresponding to the temperature=10° C. and the charging rate=90% and the internal resistance R13 corresponding to the temperature=20° C. and the charging rate=80%, and the corresponding internal resistance may then be calculated. Further, the corresponding internal resistance may be calculated based on the internal resistances R12 to R14 and R16 under the respective conditions surrounding the measurement conditions.

### Main Effects According to this Embodiment

According to this embodiment, the determination process can be performed without normalizing the measured internal resistance, so that the load of the control unit 26 is reduced.

Also, the internal resistance under the condition in which the recording axis is not provided can be calculated by linear interpolation, so that the determination process under each condition can be executed while the amount of data of the internal resistance management table 350 is reduced.

Also, at the time of shipping, the internal resistance management table 350 is stored in the battery pack 1, so that the determination process according to this embodiment can be executed immediately after the use is started.

The inventions made by the present inventors have been specifically described above based on the embodiments, but the present invention is not limited to the embodiments, and needless to say, various modifications can be made in the scope not departing from its purport.

What is claimed is:

1. A semiconductor device comprising:
a temperature measurement unit measuring the temperature of a battery cell;
a voltage measurement unit measuring the voltage of the battery cell;
an electric current measurement unit measuring an electric current supplied from the battery cell; and
a control unit,
wherein the control unit counts the number of cycles of the charging and discharging of the battery cell, measures the charging rate of the battery cell based on the voltage, measures the internal resistance of the battery cell based on the voltage and the electric current, normalizes the internal resistance based on each of the number of cycles, the temperature, and the charging rate to calculate the shipping internal resistance of the battery cell, and performs, based on the shipping internal resistance, a determination process of whether the battery cell is a non-authenticated product.

2. The semiconductor device according to claim 1,
wherein the control unit multiplies a first normalization coefficient corresponding to the number of cycles by the internal resistance to calculate a first shipping internal resistance, multiplies a second normalization coefficient corresponding to the temperature by the internal resistance to calculate a second shipping internal resistance, multiplies a third normalization coefficient corresponding to the charging rate by the internal resistance to calculate a third shipping internal resistance, and performs the determination process based on the first shipping internal resistance, the second shipping internal resistance, and the third shipping internal resistance.

3. The semiconductor device according to claim 2,
wherein the control unit derives the first normalization coefficient corresponding to the counted number of cycles from first reference information associating the number of cycles with the first normalization coefficient, derives the second normalization coefficient corresponding to the measured temperature from second reference information associating the temperature with the second normalization coefficient, and derives the third normalization coefficient corresponding to the measured charging rate from third reference information associating the charging rate with the third normalization coefficient.

4. The semiconductor device according to claim 3,
wherein the first reference information includes a table associating the number of cycles with the first normalization coefficient,
wherein the second reference information includes a table associating the temperature with the second normalization coefficient,
wherein the third reference information includes a table associating the charging rate with the third normalization coefficient.

5. The semiconductor device according to claim 3,
wherein the first reference information includes a function deriving the first normalization coefficient in which the number of cycles is a variable,
wherein the second reference information includes a function deriving the second normalization coefficient in which the temperature is a variable,
wherein the third reference information includes a function deriving the third normalization coefficient in which the charging rate is a variable.

6. The semiconductor device according to claim 2,
wherein the control unit compares each of the first shipping internal resistance, the second shipping internal resistance, and the third shipping internal resistance with the allowable range of the shipping internal resistance allowed as an authenticated product, and when any one of the first shipping internal resistance, the second shipping internal resistance, and the third shipping internal resistance is outside the allowable range, the control unit determines that the battery cell is a non-authenticated product.

7. The semiconductor device according to claim 6,
wherein when determining that the battery cell is an authenticated product, the control unit calculates the first shipping internal resistance, the second shipping internal resistance, and the third shipping internal resistance again to perform the determination process.

8. The semiconductor device according to claim 1,
wherein the control unit multiplies a fourth normalization coefficient corresponding to a combination of the number of cycles, the temperature, and the charging rate by the internal resistance to calculate a fourth shipping internal resistance, and performs the determination process based on the fourth shipping internal resistance.

9. The semiconductor device according to claim 8,
wherein the control unit derives the first normalization coefficient corresponding to the counted number of cycles from the first reference information associating the number of cycles with the first normalization coefficient, derives the second normalization coefficient corresponding to the measured temperature from the second reference information associating the temperature with the second normalization coefficient, derives the third normalization coefficient corresponding to the measured charging rate from the third reference information associating the charging rate with the third normalization coefficient, and multiplies the first normalization coefficient, the second normalization coefficient, and the third normalization coefficient to derive the fourth normalization coefficient.

10. The semiconductor device according to claim 8,
wherein the control unit derives the fourth normalization coefficient corresponding to a combination of the counted number of cycles, the measured temperature, and the measured charging rate from fourth reference information associating the combination of the number of cycles, the temperature, and the charging rate with the fourth normalization coefficient.

11. The semiconductor device according to claim 10,
wherein the fourth reference information includes a table associating a combination of the number of cycles, the temperature, and the charging rate with the fourth normalization coefficient.

12. The semiconductor device according to claim 10,
wherein the fourth reference information includes a function deriving the fourth normalization coefficient in which the number of cycles, the temperature, and the charging rate are variables.

13. The semiconductor device according to claim 11,
wherein the semiconductor device includes a fourth reference information storing register storing the fourth reference information,
wherein the fourth reference information is written into the fourth reference information storing register before the shipping of the battery cell.

14. The semiconductor device according to claim 8,
wherein the control unit compares the fourth shipping internal resistance with the allowable range of the shipping internal resistance allowed as an authenticated product, and when the fourth shipping internal resistance is outside the allowable range, the control unit determines that the battery cell is a non-authenticated product.

15. The semiconductor device according to claim 14,
wherein when determining that the battery cell is an authenticated product, the control unit calculates the fourth shipping internal resistance again to perform the determination process.

16. A semiconductor device comprising:
a temperature measurement unit measuring the temperature of a battery cell;
a voltage measurement unit measuring the voltage of the battery cell;
an electric current measurement unit measuring an electric current supplied from the battery cell; and
a control unit,
wherein the control unit measures the charging rate of the battery cell based on the voltage, measures the internal resistance of the battery cell based on the voltage and the electric current, and records the measured internal resistance into an internal resistance management table including a temperature recording axis and a charging rate recording axis based on the temperature and the charging rate during measurement, and when the internal resistance at the same temperature and the same charging rate is measured again, the control unit compares the measured internal resistance with the corresponding internal resistance recorded into the internal resistance management table to perform the determination process of whether the battery cell is a non-authenticated product.

17. The semiconductor device according to claim 16,
wherein the control unit calculates the difference between the internal resistance measured again and the corresponding internal resistance recorded into the internal resistance management table, and compares the difference with a difference allowable range allowed as an authenticated product, and when the difference is outside the difference allowable range, the control unit determines that the battery cell is a non-authenticated product.

18. The semiconductor device according to claim 16,
wherein when the temperature recording axis corresponding to the temperature during measurement is not provided in the internal resistance management table, the control unit calculates a temperature interpolation internal resistance based on the internal resistance corresponding to the temperature during measurement on each of the temperature recording axes corresponding to a plurality of the temperatures near the temperature during measurement, calculates the difference between the measured internal resistance and the temperature interpolation internal resistance, and compares the difference with the difference allowable range allowed as an authenticated product, and when the difference is outside the difference allowable range, the control unit determines that the battery cell is a non-authenticated product.

19. The semiconductor device according to claim 16,
wherein when the charging rate recording axis corresponding to the charging rate during measurement is not provided in the internal resistance management table, the control unit calculates a charging rate interpolation internal resistance based on the internal resistance corresponding to the charging rate during measurement on each of the charging rate recording axes corresponding to a plurality of the charging rates near the charging rate during measurement, calculates the difference between the measured internal resistance and the charging rate interpolation internal resistance, and compares the difference with the difference allowable range allowed as an authenticated product, and when the difference is outside the difference allowable range, the control unit determines that the battery cell is a non-authenticated product.

20. The semiconductor device according to claim 16,
wherein the semiconductor device includes an internal resistance management table storing register storing the internal resistance management table, and
wherein the internal resistance management table is written into the internal resistance management table storing register before the shipping of the battery cell.
